(19) United States
(12) Patent Application Publication
(10) Pub. No.: US 2026/0160820 A1
(43) Pub. Date: Jun. 11, 2026

(54) Electrochemical Impedance Spectroscopy Using a Charge Transfer Circuit

(71) Applicant: TEXAS INSTRUMENTS INCORPORATED, Dallas, TX (US)

(72) Inventors: Shanguang Xu, Plano, TX (US); Pradeep Shenoy, Richardson, TX (US); Darwin Fernandez, Plano, TX (US); Bassem Ibrahim, Allen, TX (US); David P Magee, Allen, TX (US)

(21) Appl. No.: 19/254,175

(22) Filed: Jun. 30, 2025

Related U.S. Application Data
(60) Provisional application No. 63/730,631, filed on Dec. 11, 2024.

(51) Int. Cl. G01R 31/389; G01R 31/3842; H01M 10/42; H01M 10/44; H01M 10/48

(52) U.S. Cl. CPC G01R 31/389; G01R 31/3842; H01M 10/4285; H01M 10/441; H01M 10/482; H01M 2220/20

(57) ABSTRACT

A battery system includes a first battery pack having a first positive terminal and a first negative terminal and having a second battery pack having a second positive terminal and a second negative terminal. The second negative terminal is coupled to the first negative terminal. A charge transfer circuit has first, second, and third circuit terminals. The first circuit terminal is coupled to the first positive terminal. The second circuit terminal is coupled to the second positive terminal. The third circuit terminal is coupled to first and second negative terminals.

### CROSS-REFERENCE TO RELATED APPLICATIONS

This application claims priority to U.S. Provisional Application No. 63/730,631, filed Dec. 11, 2024, titled “Dual Active Half Bridge Converter for EIS (Electrochemical Impedance Spectroscopy) Applications,” which is hereby incorporated by reference.

### BACKGROUND

Spectroscopy is commonly used in several fields such as electrical spectroscopy, mechanical spectroscopy, optical spectroscopy and electrochemical impedance spectroscopy. One way of performing a spectroscopy measurement is by providing an excitation stimulus (e.g., a voltage or a current) to a device under test (e.g., a battery), and measuring a response of the device under test (DUT) to the stimulus (e.g., a voltage response to a current stimulus, a current response to a voltage stimulus), and repeating the excitation and response measurement at different frequencies. Electrochemical impedance spectroscopy (EIS) may be beneficial for evaluating the state of a battery such as the battery pack of an electric vehicle (EV).

### SUMMARY

In one example, a battery system includes a first battery pack having a first positive terminal and a first negative terminal and having a second battery pack having a second positive terminal and a second negative terminal. The second negative terminal is coupled to the first negative terminal. A charge transfer circuit has first, second, and third circuit terminals. The first circuit terminal is coupled to the first positive terminal. The second circuit terminal is coupled to the second positive terminal. The third circuit terminal is coupled to first and second negative terminals.

In another example, an apparatus includes a first half-bridge having a first terminal, a second terminal, and a first switching terminal. A second half-bridge has a third terminal, a fourth terminal, and a second switching terminal. A charge storage circuit is coupled between the first and second switching terminals. A first switch has first and second switch terminals. The first switch terminal is coupled to the third terminal, and the second switch terminal is coupled to the second terminal. A second switch has third and fourth switch terminals. The third switch terminal is coupled to the fourth terminal, and the fourth switch terminal is coupled to the second terminal.

In yet another example, a method includes closing a switch coupled between a first terminal of a first battery pack and a second terminal of a second battery pack. The first battery pack has at least one cell, and the second battery pack also has at least one cell. The method further includes transferring a charge from the first battery pack to the second battery pack through a circuit and measuring a current through the circuit resulting from the charge. The method also includes measuring at least one of a first voltage of the at least one cell of the first battery pack or a second voltage of the at least one cell of the second battery pack and generating at least one of a first impedance spectroscopy of the first battery pack or a second impedance spectroscopy of the second battery pack based on the current and the least one of the first or second voltages.

### BRIEF DESCRIPTION OF THE DRAWINGS

FIG. 1 is a system diagram of a battery system that includes a charge transfer circuit, in an example.

FIG. 2 is a system diagram of a battery system that includes a charge transfer circuit, in another example.

FIG. 3 is a system diagram of a battery system that includes a charge transfer circuit, in yet another example.

FIG. 4 is a graph of signals in the charge transfer circuit of FIGS. 1-3.

FIG. 5 is a graph of example current flow in charge and discharge phases during excitation current generation in the examples of FIGS. 1-3.

FIG. 6 a flow diagram for an example method of electrochemical impedance spectroscopy that generates an excitation current by transferring charge between battery packs.

### DETAILED DESCRIPTION

The same reference numbers or other reference designators are used in the drawings to designate the same or similar (either by function and/or structure) features.

Spectroscopy measurement, such as electrochemical impedance spectroscopy measurement, are performed on batteries to analyze the behavior of the battery, which can indicate various operation operations of the battery. Specifically, battery behavior varies while supplying current based on battery condition as well as environmental effects. Prediction of battery behavior during its run time is helpful to manage and improve the performance of the battery. The battery condition is often characterized by the level of available charge, such as a state of charge (SOC), and the percentage of useful charge/discharge cycles that remain, such as a state of health (SOH). The battery impedance spectrum, which is the ratio between the battery cell voltage and current in the frequency domain, has a strong correlation to battery SOC, SOH, and internal temperature. EIS entails measuring the battery's impedance spectra. EIS measurements can be used to determine the battery's impedance spectra, which in turn, can help determine the SOC, SOH, and/or temperature parameters. The EIS technique described herein may apply to EVs or other battery-operated systems.

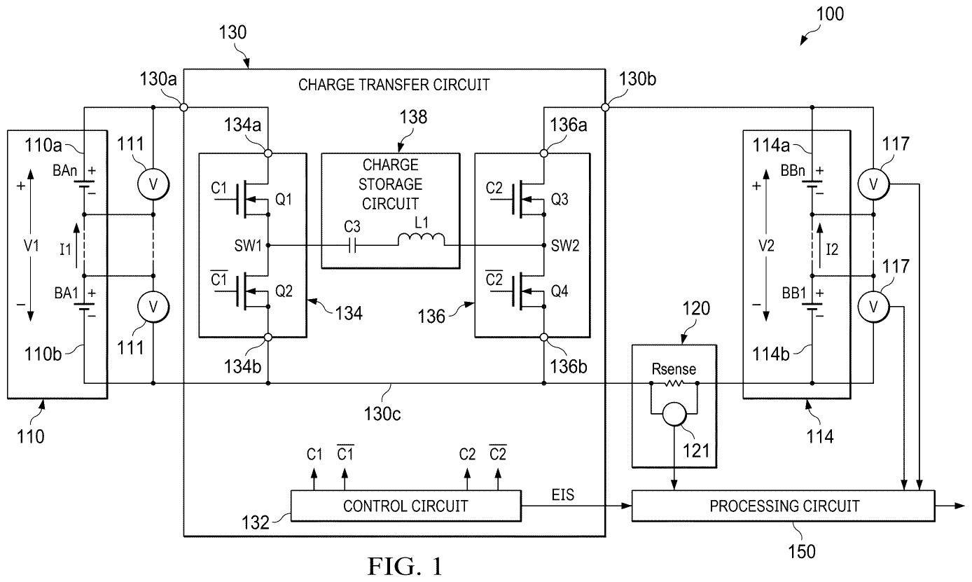

FIG. 1 is a system diagram of a charge transfer circuit 130 coupled to a first battery pack 110, a second battery pack 114, and a processing circuit 150. The battery packs 110 and 114 may be part of, for example, an electric vehicle's battery system. Battery pack 110 has a positive terminal 110a and a negative terminal 110b. Battery pack 114 has a positive terminal 114a and a negative terminal 114b. The negative terminals 110b and 114b of battery packs 110 and 114 in the example of FIG. 1 are coupled together. Accordingly, battery packs 110 and 114 share a common ground reference that differs only by a small voltage drop across sense resistor Rsense. Battery pack 110 includes one or more cells BA1 through BAn, and battery pack 114 also includes one or more cells BB1 through BBn. Charge transfer circuit 130 has terminals 130a, 130b, and 130c. Terminal 130a is coupled to the positive terminal 110a of battery pack 110. Terminal 130b is coupled to the positive terminal 114a of battery pack 114. Terminal 130c is coupled to the negative terminals 110b and 114b of battery packs 110 and 114.

In the example of FIG. 1, charge transfer circuit 130 includes a half-bridge 134, a half-bridge 136, a control circuit 132, and a charge storage circuit 138. Charge storage circuit 138 includes a capacitor C3 coupled to an inductor L1. Half-bridge 134 includes transistors Q1 and Q2. Transistors Q1 and Q2 may be n-channel field effect transistors (NFETs). The drain of Q1 is coupled to a terminal 134a of half-bridge 134, and the source of Q2 is coupled to a terminal 134b of half-bridge 134. The source of Q1 is coupled to the drain of Q2 at a switching terminal SW1. Terminals 134a and 134b are coupled to terminals 130a and 130c, respectively, of charge transfer circuit 130. Half-bridge 136 includes transistors Q3 and Q4. Transistors Q3 and Q4 also may be NFETs. The drain of Q3 is coupled to a terminal 136a of half-bridge 136, and the source of Q4 is coupled to a terminal 136b of half-bridge 136. The source of Q3 is coupled to the drain of Q4 at a switching terminal SW2. Terminals 136a and 136b are coupled to terminals 130b and 130c, respectively, of charge transfer circuit 130. One terminal of capacitor C3 is coupled to switching terminal SW1 of half-bridge 134, and the other terminal of capacitor C3 is coupled to a terminal of inductor L1. The other terminal of inductor L1 is coupled to switching terminal SW2 of half-bridge 136. The capacitance of the capacitor C3 and the inductance of the inductor L1 can be relatively small. For example, the inductance of the inductor L1 may be 50 nanohenries (nH) and the capacitance of the capacitor C3 may be 3 microfarads (μF).

A voltage sensor 111 is coupled to each cell BA1: BAn of battery pack 110. Similarly, a voltage sensor 117 is coupled to each cell BB1: BBn of battery pack 114. Each voltage sensor 111, 117 measures the voltage across the respective cell. The outputs of the voltage sensors 111, 117 are coupled to processing circuit 150. The voltage sensors 111, 117 may be part of the respective battery packs 110, 114 or may be part of charge transfer circuit 130. A current sensor 120 is coupled between the negative terminals 110b and 114b of battery packs 110 and 114. In the example of FIG. 1, current sensor 120 includes a sense resistor Rsense couple to an amplifier 121. Amplifier 121 has an output coupled to processing circuit 150. Amplifier 121 amplifies the voltage developed across sense resistor Rsense and provides a signal to control circuit 132 indicative of the current through the sense resistor Rsense.

The gates of Q1-Q4 are coupled to control circuit 132. Control circuit 132 provides control signals C1, [symbol] (logical inverse of C1), C2, and [symbol] (logical inverse of C2) to the gates of Q1, Q2, Q3, and Q4, respectively, to turn on and off each of Q1-Q4 in accordance with an EIS technique described below. The EIS technique causes a time-varying current to flow through each battery pack 110, 114. The resulting current (as determined by sense resistor Rsense and amplifier 121) and the individual cell voltages (as determined by voltage sensors 111 and 117) are provided to processing circuit 150. Control circuit 132 generates a signal EIS to processing circuit 150 to indicate to control circuit 132 when an EIS measurement is to occur. Processing circuit 150 receives the signal from amplifier 121 indicative of current through the sense resistor Rsense and the various signals from voltage sensors 111 and 117. In one example, processing circuit 150 computes a discrete Fourier transform (DFT) of the current and of the voltages and calculates the ratio of voltage to current at different frequencies to produce an impedance spectrum. Processing circuit 150 may output values indicative of the impedance spectrum to other components, e.g., a microcontroller unit. In one example, processing circuit 150 is a microcontroller that executes machine code. In another example, processing circuit 150 is a discrete digital circuit.

In accordance with the below-described EIS technique, as the EIS measurement is being made, charge is transferred from one battery pack to the charge storage circuit 138 and then charge is transferred from the charge storage circuit 138 to the other battery pack. For example, charge is transferred from battery pack 110 to charge storage circuit 138 and then from charge storage circuit 138 to battery pack 114. Similarly, charge is transferred from battery pack 114 to charge storage circuit 138 and then from charge storage circuit 138 to battery pack 110. The charge transfer circuit 130 advantageously causes a time-varying current to flow through each battery pack so that processing circuit 150 can determine an impedance spectrum without a substantial depletion of the charge in either battery pack 110, 114.

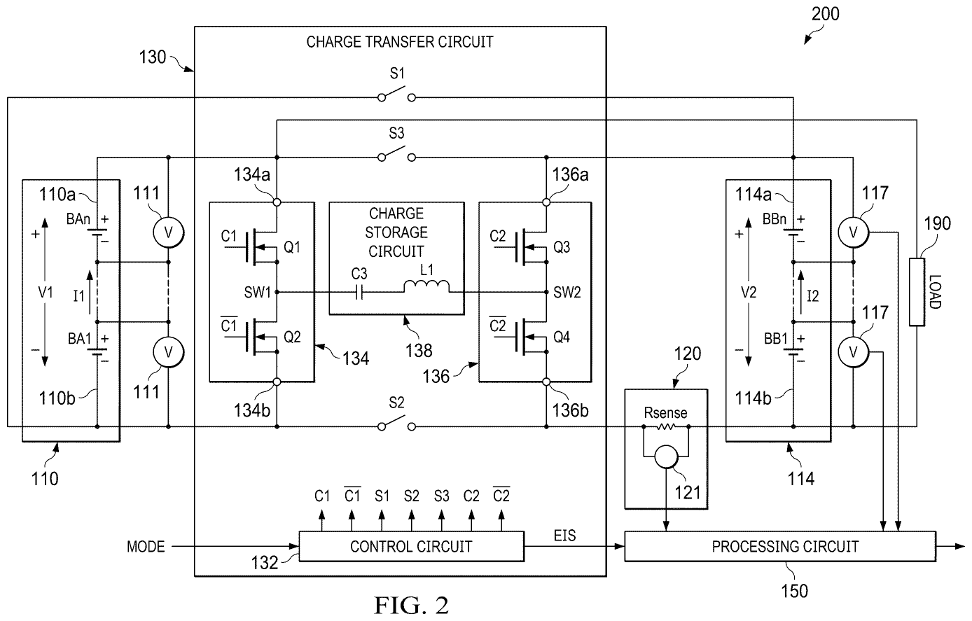

In an example in which a battery system may be configured in different configurations to yield different voltages, the EIS system described below in FIG. 2 can determine the impedance spectrum of the battery system regardless of the configuration of the battery system. For example the voltage produced by an EV's battery system may be, for example, 400V or 800V. Some EVs having an 800V battery system may configure the battery system as an 800V battery pack or configure the battery system as two-400V battery packs coupled in parallel. This configurability of the battery system may allow the EV to configure its battery system in a higher voltage mode (e.g., 800V) when the EV is coupled to a higher voltage charger (e.g., an 800V charger) or in a lower voltage mode (e.g., 400V) when the EV is coupled to a lower voltage charger (e.g., a 400V charger). The EIS system described below in FIG. 2 can determine the impedance spectrum of the battery system regardless of the mode (e.g., higher voltage mode or lower voltage mode) for which the battery system is configured.

FIG. 2 is a system diagram of charge transfer circuit 130 coupled to battery packs 110 and 114 and processing circuit 150, in another example. This example also includes switches S1, S2, and S3 (e.g., transistors). Switches S1-S3 may be part of charge transfer circuit 130 or separate from charge transfer circuit 130. Control circuit 132 has control outputs coupled to control terminals of respective switches S1-S3. A load 190 also is shown coupled between the positive terminal 110a of battery pack 110 and the negative terminal 114b of battery pack 114. The load 190 may include, for example, an inverter for a motor of an EV.

In the example of FIG. 2, the battery system may be configured in a lower voltage mode or in a higher voltage mode in accordance with a MODE signal received by control circuit 132. The higher voltage mode may be applicable if, for example, the EV is to be charged by a charger capable of charging the battery system at a higher voltage. The lower voltage mode may be applicable if the EV is to be charged by a charger which operates at a lower voltage. If the MODE signal indicates (e.g., logic high) that the battery system should be configured in a higher voltage mode, control circuit 132 responds by closing switch S1 and opening switches S2 and S3. If the MODE signal indicates (e.g., logic low) that the battery system should be configured in a lower voltage mode, control circuit 132 responds by closing switches S2 and S3 and opening switch S1.

In the higher voltage mode, with switch S1 closed, the positive terminal 114a of battery pack 114 is coupled to the negative terminal 110b of battery pack 110. In this configuration, battery packs 110 and 114 are coupled in series thereby producing a voltage that is the sum of the voltages of the individual battery packs. For example, if each battery pack 110, 114 is a 400V battery pack, the series combination of battery packs 110 and 114 produces 800V to power load 190. In the lower voltage mode, with switches S2 and S3 closed, the battery packs 110 and 114 are coupled in parallel and load 190 is coupled to the parallel combination of the battery packs. Control circuit 132 can cause an EIS measurement to be made while the switch S1 is closed and the battery packs 110 and 114 are coupled in series. To make an EIS measurement while in the lower voltage mode, control circuit 132 opens switch S3 and closes (or maintains closed) switch S2.

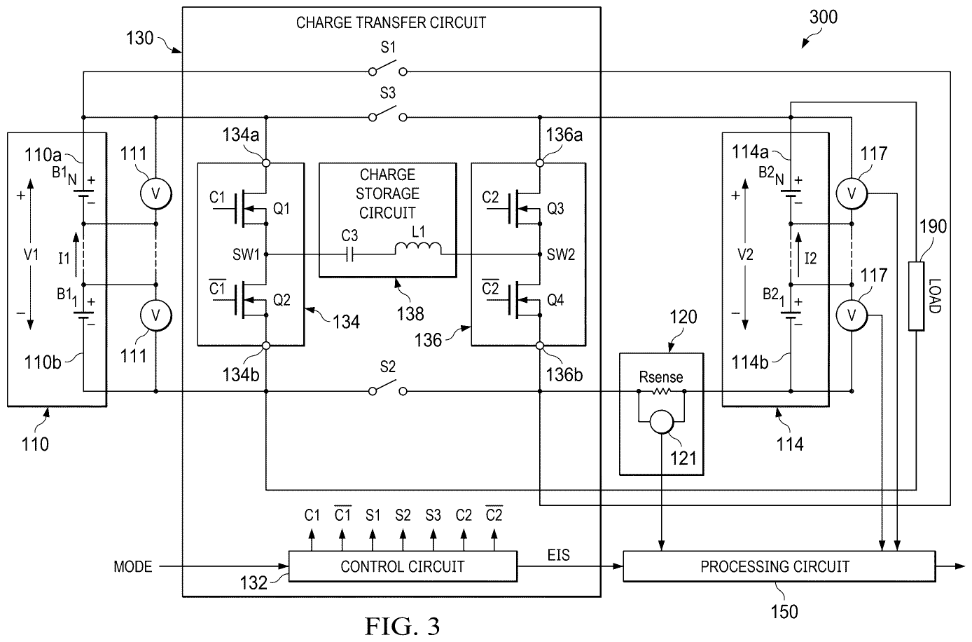

FIG. 3 is similar to FIG. 2. In FIG. 3, one terminal of switch S1 is coupled to the positive terminal 110a of battery pack 110 and the other terminal of switch S1 is coupled to the terminal 136b of half-bridge 136. Further, in FIG. 3 one terminal of load 190 is coupled to the positive terminal 114a of battery pack 114 and the other terminal of load 190 is coupled to the negative terminal 110b of battery pack 110. As was the case for the example of FIG. 2, control circuit 132 can cause an EIS measurement to be made while switch S1 is closed and the battery packs 110 and 114 are coupled in series. Control circuit 132 also can cause an EIS measurement to be made while in the lower voltage mode with switch S3 open and switch S2 closed.

Control circuit 132 generates driver control signals C1, [symbol] , C2, and [symbol] to control the corresponding transistors Q1-Q4 to manage the drawing of excitation current and transfer of charge between the battery packs 110 and 114. Control circuit 132 generates a switching cycle at the rate of a switching frequency f_{sw} that includes two phases—phase 1 and phase 2. One phase is used for discharging one of the battery packs into the charge storage circuit 138 which stores the transferred charge (e.g., in inductor L1), and the other phase is used for charging the other battery pack with the charge stored in the charge storage circuit 138.

With regard to any of the examples of FIGS. 1-3, to measure the impedance spectrum of battery pack 110, charge transfer circuit 130 draws excitation current from the battery pack 110, stores the charge drawn from battery pack 110, and transfers the charge to the battery pack 114. The current sensor 120 measures the excitation current drawn from battery pack 110 and provides a current measurement signal to processing circuit 150. Voltage sensors 111 measures the voltage across the respective cells of battery pack 110 as the excitation current is drawn and provide voltage measurement signals to processing circuit 150. Charge storage circuit 138 stores the energy of the excitation current, e.g., in inductor L1. Charge transfer circuit 202 transfers the stored energy from charge storage circuit 138 to battery pack 114.

To measure the impedance spectrum of battery pack 114, charge transfer circuit 130 draws excitation current from battery pack 144, stores the charge drawn from battery pack 114, and transfers the charge to the battery pack 110. Current sensor 120 measures the excitation current drawn battery pack 114 and provides a current measurement signal to processing circuit 150. Voltage sensors 117 measure the voltage across the respective cells of battery pack 114 as the excitation current is drawn and provide voltage measurement signals to processing circuit 150. Charge transfer circuit 130 stores the energy of the excitation current in charge storage circuit 138 (e.g., in inductor L1). Charge transfer circuit 130 transfers the stored energy from charge storage circuit 138 to battery pack 110. By transferring the energy of the excitation current between battery packs 110 and 114, relatively little charge is lost from battery packs 110 and 114 during an EIS measurement. Specifically, the loss is from the drain-to-source on-resistance (Rdson) of transistors Q1-Q4 and the power dissipation in current sensor 120.

During phase 1, charge is transferred from battery pack 114 to charge storage circuit 138 by turning on transistor Q4 and turning off transistor Q3 in the half-bridge 136 followed by turning on the transistor Q2 and turning off transistor Q1 after a time delay t_{delay}. During phase 2, charge is transferred from charge storage circuit 138 to battery pack 110 by turning off transistor Q4 and turning on the transistor Q3 of the half-bridge circuit 136 followed by turning off transistor Q2 and turning on transistor Q1 after the same time delay t_{delay}.

During phase 1, current flows through battery pack 114, while no current flows through battery pack 110. Then in phase 2, current flows through the cells of battery pack 110 in the opposite direction relative to phase 1, while no current flows through battery pack 114. The amplitude of the current of each switching cycle is controlled by the phase φ(t) difference between control signals C1 and C2 according to the desired sinusoidal excitation. The φ(t) can be positive or negative by lagging or leading the control signals of the half-bridge circuit 304 relative to the half-bridge circuit 302. Therefore, the excitation signal can be centered around zero without direct current (DC) current to reduce power loss. The polarity of the phase φ(t), which controls the charging and discharging phases for battery packs 110 and 114, determines the excitation signal amplitude. The average current in each battery pack, which can be determined using a low-pass filter to remove the high-frequency switching components, may be equal to the desired sinusoidal excitation waveform through the battery packs. Using this approach, exchanging of charge between battery packs during a single EIS measurement allows the battery packs to maintain their initial charge capacity with only small losses.

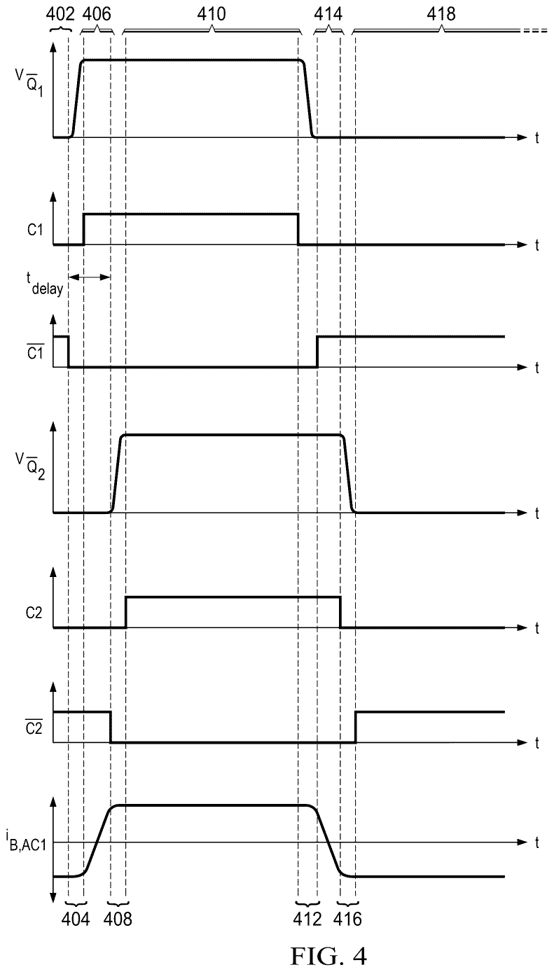

FIG. 4 is a graph of signals in the charge transfer circuit 130 that illustrate transfer of charge from battery pack 114 to the battery pack 110 during switching cycles of the half-bridge circuits 136 and 138. In the interval 402, control circuit 132 provides [symbol] and [symbol] in a first state to turn on transistors Q2 and Q4, and provides C1 and C2 in a second state to turn off transistors Q1 and Q3. The voltage across the transistors Q2 and Q4 is zero or near zero. The current I2 through battery pack 114 is negative.

In the interval 404, control circuit 132 provides [symbol] in the first state to turn on transistor Q4, and provides C1, [symbol] , and C2 in the second state ( [symbol] transitions from the second state to the first state) to turn off transistors Q1, Q2, and Q3. Transistor Q2 may be turned off with zero voltage switching. The voltage across transistor Q2 (e.g., drain-to-source voltage) increases.

In the interval 406, after the voltage across transistor Q2 has risen to a selected value, control circuit 132 may provide C1 in the first state to turn on transistor Q1. Current flows through transistor Q3 due to the battery pack voltage across the inductor L1. In this configuration, transistors Q2 and Q3 are off, and transistors Q1 and Q4 are on to provide a path for current flow. Capacitor C3 may provide capacitive isolation between battery packs 110 and 114 and may have a relatively low voltage tolerance (e.g., 5 V). The voltage across capacitor C3 may be an average of the voltage across battery pack 114 and the voltage across the battery pack 110. The voltage across inductor L1, which has opposite polarity from the voltage across the capacitor C3 (so that the total voltage is zero as switch nodes SW1 and SW2 are shorted together by transistors Q2 and Q3), causes current flowing through the inductor L1 to increase (e.g., ramps up), and the ramp rate can be determined by the inductance of inductor L1. The duration of interval 406 may determine the amount of increase of the current before it stops increasing, and the amount of charge being transferred.

In the interval 408, after the current flowing through inductor L1 has increased to a selected value, control circuit 132 provides control signal [symbol] in the second state to turn off transistor Q4. In this configuration, transistors Q2, Q3, and Q4 are off, and transistor Q1 is on. The voltage across transistor Q2 (e.g., the drain-to-source voltage) increases.

In the interval 410, after the voltage across transistor Q2 has increased to a selected value, control circuit 132 provides control signal C2 in the first state to turn on transistor Q3 with zero voltage switching. In this configuration, transistors Q2 and Q4 are off and transistors Q1 and Q3 are on. The voltage across inductor L1 is zero, and the current through inductor L1 stays at (or near) the selected value. In the interval 410 (the power transfer interval), charge is transferred to battery pack 110 from the charge storage circuit 138. Accordingly, the charge transferred from battery pack 114 to the charge storage circuit 138 is transferred to battery pack 110.

In the interval 412, control circuit 132 provides control signal C1 in the second state to turn off transistor Q1. The voltage across transistor Q4 falls.

In the interval 414, after the voltage across transistor Q4 has fallen to a selected value, control circuit 132 provides control signal [symbol] in the first state to turn on transistor Q2 with zero voltage switching.

In the interval 416, when the current flowing through inductor L1 has fallen to a selected value, control circuit 132 provides control signal C2 in the second state to turn off transistor Q3. The voltage across transistor Q2 falls.

In the interval 418, when the voltage across transistor Q2 has fallen to a selected value, control circuit 308 provides control signal [symbol] in the first state to turn on transistor Q2 with zero voltage switching. In the interval 418, charge transfer circuit 130 is back in the same state as was the case for interval 402 for execution of a successive charge transfer cycle.

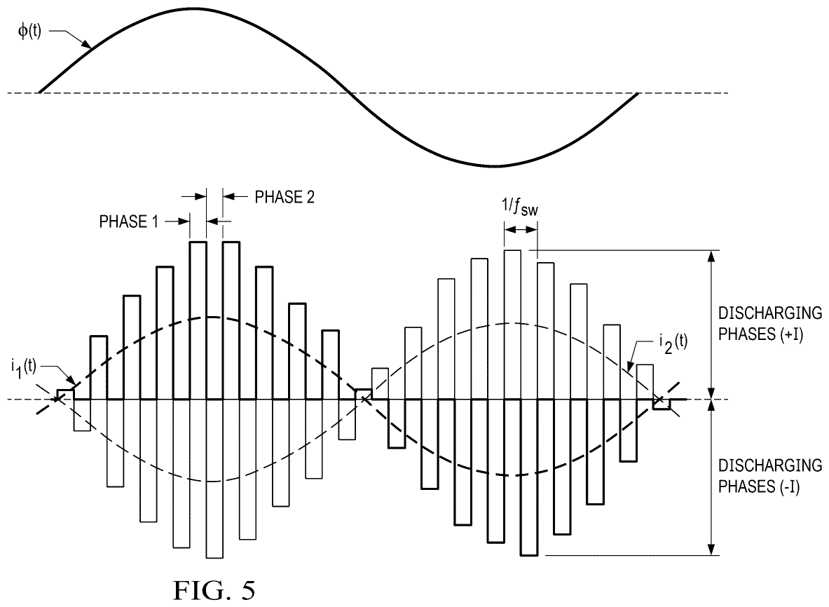

FIG. 5 is a graph of example current flow through battery packs 110 and 114. In FIG. 5, i₁(t) is the current flow in phase 1 through battery pack 114 and i₂(t) is the current flow in phase 2 through battery pack 110. The amplitude of the current of each switching cycle is controlled by the phase φ(t) according to a desired sinusoidal excitation. The φ(t) can be positive or negative by lagging or leading the control signals of the half-bridge circuit 134 relative to the half-bridge circuit 136. Therefore, the excitation signal can be centered around zero without DC current to reduce power loss. The polarity of the phase φ(t), which controls the charging and discharging phases for the battery packs, determines the excitation signal amplitude. The average current in each of the battery packs 110 and 114, which can be determined using a low-pass filter to remove the high-frequency switching components, may be equal to the desired sinusoidal excitation waveform through the battery packs.

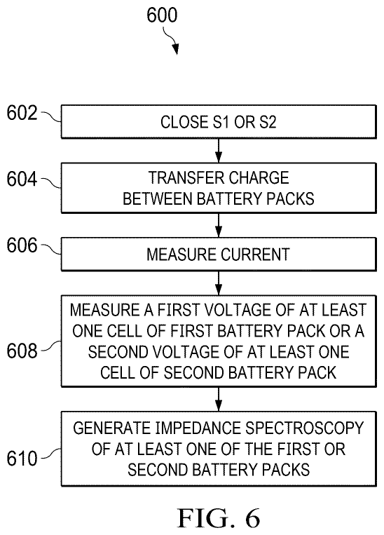

FIG. 6 is a flow diagram for an example method 600 of EIS that generates an excitation current by transferring charge between battery packs. Though depicted sequentially as a matter of convenience, at least some of the actions shown may be performed in a different order and/or performed in parallel. Additionally, some implementations may perform only some of the actions shown. Operations of the method 600 may be performed by the system 200 or system 300.

In block 602, switch S1 or S2 is closed, and switch S3 is open. In one example, control circuit 132 closes either switch S1 or S2 in response to the MODE signal, as described above.

In block 604, charge is transferred between battery packs 110 and 114 through a circuit (e.g., charge transfer circuit 130). Transferring the charge may include transferring the charge from one of the battery packs to charge storage circuit 138 of charge transfer circuit 130 followed by transferring the charge stored in the charge storage circuit 138 to the other battery pack.

In block 606, the current flowing during the transfer of charge in block 604 is measured. For example, current sensor 120 may measure the current flowing during the charge transfer.

In block 608, a voltage across the cells of one of the battery packs and/or the voltage across the cells of the other battery pack is measured. For example, the voltage sensors 111 and 117 may measure the voltage across the corresponding battery cells.

In block 610, processing circuit 150 generates an impedance spectroscopy of battery pack 110 or battery pack 114 based on the current measured in block 606 and the voltages measured in block 608. For example, processing circuit 150 receives the current and voltage measurements from current sensor 120 and voltage sensors 111, 117 and computes an impedance value for each cell in the battery pack based on the measured voltage across the corresponding cell and the measured excitation current. For example, processing circuit 150 may sample and digitize the measured current and voltages received from the current sensor 120 and the voltage sensors 111/117 and compute a discrete Fourier transform (DFT) of the current and voltage signals. Processing circuit 150 may compute impedance values for each cell in the battery pack as a ratio of the voltage DFT and the current DFT at each excitation frequency. Processing circuit 150, or circuitry coupled to the processing circuit 150, may determine an attribute (temperature, SOC, SOH, etc.) of each cell of the battery pack based on the impedance values.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

Also, in this description, the recitation “based on” means “based at least in part on.” Therefore, if X is based on Y, then X may be a function of Y and any number of other factors.

A device that is “configured to” perform a task or function may be configured (e.g., programmed and/or hardwired) at a time of manufacturing by a manufacturer to perform the function and/or may be configurable (or reconfigurable) by a user after manufacturing to perform the function and/or other additional or alternative functions. The configuring may be through firmware and/or software programming of the device, through a construction and/or layout of hardware components and interconnections of the device, or a combination thereof.

As used herein, the terms “terminal”, “node”, “interconnection”, “pin” and “lead” are used interchangeably. Unless specifically stated to the contrary, these terms are generally used to mean an interconnection between or a terminus of a device element, a circuit element, an integrated circuit, a device or other electronics or semiconductor component.

A circuit or device that is described herein as including certain components may instead be adapted to be coupled to those components to form the described circuitry or device. For example, a structure described as including one or more semiconductor elements (such as transistors), one or more passive elements (such as resistors, capacitors, and/or inductors), and/or one or more sources (such as voltage and/or current sources) may instead include only the semiconductor elements within a single physical device (e.g., a semiconductor die and/or integrated circuit (IC) package) and May be adapted to be coupled to at least some of the passive elements and/or the sources to form the described structure either at a time of manufacture or after a time of manufacture, for example, by an end-user and/or a third-party.

While the use of particular transistors is described herein, other transistors (or equivalent devices) may be used instead with little or no change to the remaining circuitry. For example, a field effect transistor (“FET”) (such as an n-channel FET (NFET) or a p-channel FET (PFET)), a bipolar junction transistor (BJT—e.g., NPN transistor or PNP transistor), an insulated gate bipolar transistor (IGBT), and/or a junction field effect transistor (JFET) may be used in place of or in conjunction with the devices described herein. The transistors may be depletion mode devices, drain-extended devices, enhancement mode devices, natural transistors or other types of device structure transistors. Furthermore, the devices may be implemented in/over a silicon substrate (Si), a silicon carbide substrate (SiC), a gallium nitride substrate (GaN) or a gallium arsenide substrate (GaAs).

References may be made in the claims to a transistor's control input and its current terminals. In the context of a FET, the control input is the gate, and the current terminals are the drain and source. In the context of a BJT, the control input is the base, and the current terminals are the collector and emitter. The gate, source, and drain of a FET and base, collector, and emitter of a BJT are terminals of the transistor.

References herein to a FET being “ON” or “enabled” means that the conduction channel of the FET is present and drain current may flow through the FET. References herein to a FET being “OFF” or “disabled” means that the conduction channel is not present so drain current does not flow through the FET. An “OFF” FET, however, may have current flowing through the transistor's body-diode.

Circuits described herein are reconfigurable to include additional or different components to provide functionality at least partially similar to functionality available prior to the component replacement. Components shown as resistors, unless otherwise stated, are generally representative of any one or more elements coupled in series and/or parallel to provide an amount of impedance represented by the resistor shown. For example, a resistor or capacitor shown and described herein as a single component may instead be multiple resistors or capacitors, respectively, coupled in parallel between the same nodes. For example, a resistor or capacitor shown and described herein as a single component may instead be multiple resistors or capacitors, respectively, coupled in series between the same two nodes as the single resistor or capacitor.

While certain elements of the described examples are included in an integrated circuit and other elements are external to the integrated circuit, in other example embodiments, additional or fewer features may be incorporated into the integrated circuit. In addition, some or all of the features illustrated as being external to the integrated circuit may be included in the integrated circuit and/or some features illustrated as being internal to the integrated circuit may be incorporated outside of the integrated. As used herein, the term “integrated circuit” means one or more circuits that are: (i) incorporated in/over a semiconductor substrate; (ii) incorporated in a single semiconductor package; (iii) incorporated into the same module; and/or (iv) incorporated in/on the same printed circuit board.

Uses of the phrase “ground” in the foregoing description include a chassis ground, an Earth ground, a floating ground, a virtual ground, a digital ground, a common ground, and/or any other form of ground connection applicable to, or suitable for, the teachings of this description. In this description, unless otherwise stated, “about,” “approximately” or “substantially” preceding a parameter means being within +/−10 percent of that parameter or, if the parameter is zero, a reasonable range of values around zero.

Modifications are possible in the described examples, and other examples are possible, within the scope of the claims.

What is claimed is:

1. A battery system, comprising:
a first battery pack having a first positive terminal and a first negative terminal;
a second battery pack having a second positive terminal and a second negative terminal, the second negative terminal coupled to the first negative terminal; and
a charge transfer circuit having first, second, and third circuit terminals, the first circuit terminal coupled to the first positive terminal, the second circuit terminal coupled to the second positive terminal, and the third circuit terminal coupled to first and second negative terminals.

2. The battery system of claim 1, wherein the charge transfer circuit includes:
a first half-bridge coupled to the first and third circuit terminals; and
a second half-bridge coupled to the second and third circuit terminals.

3. The battery system of claim 2, wherein the charge transfer circuit includes a charge storage circuit coupled to the first and second half-bridges.

4. The battery system of claim 3, wherein the charge storage circuit includes an inductor coupled in series with a capacitor.

5. The battery system of claim 1, wherein the charge transfer circuit includes a charge storage circuit.

6. The battery system of claim 5, wherein the charge storage circuit includes an inductor coupled in series with a capacitor.

7. The battery system of claim 1, wherein the charge transfer circuit includes a charge storage circuit, and the charge transfer circuit is configured to:
transfer charge from one of the first or second battery packs to the charge storage circuit; and
transfer charge from the charge storage circuit to the other of the one of the first or second battery packs.

8. The battery system of claim 1, further comprising a processing circuit coupled to the first and second battery packs and to the charge transfer circuit, the processing circuit configured to receive a first signal representing a current through the charge transfer circuit and a second signal from at least one of the first or second battery packs representing a voltage, and provide a third signal at an output of the processing circuit representing an impedance of at least one of the first or second battery packs.

9. An apparatus, comprising:
a first half-bridge having a first terminal, a second terminal, and a first switching terminal;
a second half-bridge having a third terminal, a fourth terminal, and a second switching terminal;
a charge storage circuit coupled between the first and second switching terminals;
a first switch having first and second switch terminals, the first switch terminal coupled to the third terminal, and the second switch terminal coupled to the second terminal; and
a second switch having third and fourth switch terminals, the third switch terminal coupled to the fourth terminal, and the fourth switch terminal coupled to the second terminal.

10. The apparatus of claim 9, wherein the charge storage circuit includes an inductor coupled in series with a capacitor.

11. The apparatus of claim 9, further comprising a control circuit coupled to the first and second half-bridges, wherein the control circuit is configured to control states of the first and second half-bridges to transfer charge through the first and second half-bridge to the charge storage circuit.

12. The apparatus of claim 11, wherein the control circuit is configured to control the states of the first and second half-bridges to transfer the charge to the charge storage circuit and from the charge storage circuit when the first switch is closed and the second switch is open.

13. The apparatus of claim 11, wherein the control circuit is configured to control the states of the first and second half-bridges to transfer the charge to the charge storage circuit and from the charge storage circuit when the first switch is open and the second switch is closed.

14. The apparatus of claim 9, further comprising a third switch having fifth and sixth switch terminals, the fifth switch terminal coupled to the third terminal, and the sixth switch terminal coupled to the first terminal.

15. The apparatus of claim 9, further comprising:
a first device under test coupled to the first and second terminals;
a second device under test coupled to the third and fourth terminals; and
a control circuit coupled to the first and second half-bridges; and
wherein the control circuit is configured to control the first and second half-bridges to transfer charge from the first device under test to the charge storage circuit and to transfer charge from the charge storage circuit to the second device under test.

16. The apparatus of claim 15, further comprising a processing circuit coupled to the control circuit, the processing circuit configured to receive a first signal representing a current through the charge storage circuit and a second signal representing a voltage of at least one of the first or second devices under test, and provide a third signal at an output of the processing circuit representing an impedance of the one of the first or second devices under test.

17. A method, comprising:
closing a switch coupled between a first terminal of a first battery pack and a second terminal of a second battery pack, the first battery pack having at least one cell, and the second battery pack having at least one cell;
transferring a charge from the first battery pack to the second battery pack through a circuit;
measuring a current through the circuit resulting from the charge;
measuring at least one of a first voltage of the at least one cell of the first battery pack or a second voltage of the at least one cell of the second battery pack; and
generating at least one of a first impedance spectroscopy of the first battery pack or a second impedance spectroscopy of the second battery pack based on the current and the least one of the first or second voltages.

18. The method of claim 17, wherein closing the switch between the first terminal and the second terminal comprises closing the switch between a positive terminal of the second battery pack and a negative terminal of the first battery pack.

19. The method of claim 17, wherein closing the switch between the first terminal and the second terminal comprises closing the switch between negative terminals of the first and second battery packs.

20. The method of claim 17, wherein transferring the charge includes:
receiving the charge by discharging the first battery pack;
charging an energy storage device with the charge;
discharging the energy storage device to recover the charge; and
providing the recovered charge to the second battery pack.
